(19) United States
(12) Patent Application Publication
(10) Pub. No.: US 2026/0129782 A1
(43) Pub. Date: May 7, 2026

(54) SLIDE RAIL DEVICE FOR A SERVER CASE

(71) Applicant: FOSITEK CORPORATION, New Taipei City (TW)

(72) Inventors: Chia-Hung SU, New Taipei City (TW); Thin-Wei TSAO, New Taipei City (TW); Kuan-Wei CHEN, New Taipei City (TW)

(73) Assignee: FOSITEK CORPORATION, New Taipei City (TW)

(21) Appl. No.: 19/010,465

(22) Filed: Jan. 6, 2025

(30) Foreign Application Priority Data
Nov. 4, 2024 (TW) 113142124

(51) Int. Cl. H05K 7/14

(52) U.S. Cl. CPC H05K 7/1489

(57) ABSTRACT

A slide rail device for a server case includes an outer rail unit, a middle rail unit and an inner rail unit. The outer rail unit includes an outer rail having outer first and second ends, and an outer abutting protrusion adjacent to the outer second end. The middle rail unit includes a middle rail slidable along the outer rail, and a detent member pivotably disposed on the middle rail. The detent member is in abutting engagement with the outer abutting protrusion to prevent sliding movement of the middle rail relative to the outer rail. The inner rail unit includes an inner rail slidable along the middle rail, and a releasing member moved to abut and press the detent member, during sliding movement of the inner rail, to make the detent member turn so as to release the detent member from the outer abutting protrusion.

### CROSS-REFERENCE TO RELATED APPLICATION

This application claims priority to Taiwanese Patent Application No. 113142124, filed on Nov. 4, 2024, and incorporated by reference herein in its entirety.

### FIELD

The disclosure relates to a slide rail device, and more particularly to a slide rail device for connecting with a server case.

### BACKGROUND

A conventional slide rail device includes an outer rail, a middle rail slidably disposed on the outer rail, and an inner rail slidably disposed on the middle rail for connecting with a server case. The inner rail has a length shorter than a half of the length of the middle rail. During the operation of the slide rail device, the user pulls the server case to bring the inner rail to move relative to the middle rail, and then the middle rail is brought to move relative to the outer rail. However, the middle rail might accidentally move and project from the outer rail before the inner rail is moved out of the middle rail, which may cause the user to be scratched by the middle rail during the operation.

### SUMMARY

Therefore, an object of the disclosure is to provide a slide rail device that can alleviate at least one of the drawbacks of the prior art.

According to the disclosure, the slide rail device for a server case includes an outer rail unit, a middle rail unit and an inner rail unit. The outer rail unit includes an outer rail. The outer rail has an outer first end, an outer second end opposite to the outer first end, and at least one outer abutting protrusion disposed adjacent to the outer second end. The middle rail unit includes a middle rail which is disposed on and longitudinally slidable along the outer rail, and a detent member which is pivotably disposed on the middle rail. The middle rail has a middle first end adjacent to the outer first end, and a middle second end opposite to the middle first end. The detent member is disposed to be in abutting engagement with the outer abutting protrusion to prevent sliding movement of the middle rail relative to the outer rail. The inner rail unit includes an inner rail which is disposed on and longitudinally slidable along the middle rail for connecting with the server case, and a releasing member which is securely disposed on the inner rail to be moved with the inner rail. During sliding movement of the inner rail from the middle first end to the middle second end, the releasing member is moved to abut and press the detent member to make the detent member turn so as to release engagement of the detent member from the outer abutting protrusion.

### BRIEF DESCRIPTION OF THE DRAWINGS

Other features and advantages of the disclosure will become apparent in the following detailed description of the embodiment with reference to the accompanying drawings. It is noted that various features may not be drawn to scale.

FIG. 1 is a perspective view illustrating an embodiment of a slide rail device according to the disclosure.

FIG. 2 is an exploded perspective view of the embodiment.

FIG. 3 is an exploded perspective view of an outer rail unit of the embodiment.

FIG. 4 is a perspective view of a middle rail unit of the embodiment.

FIG. 5 is an exploded perspective view of the middle rail unit of the embodiment.

FIGS. 6 and 7 are fragmentary, exploded perspective views of the middle rail unit of the embodiment.

FIG. 8 is an exploded perspective view of an inner rail unit of the embodiment.

FIG. 9 is a perspective view of the embodiment, illustrating a state when an inner rail of the inner rail unit is moved to a middle second end of the middle rail unit.

FIG. 10 is a fragmentary rear view of the embodiment, illustrating a state when a detent member is in abutting engagement with an outer abutting protrusion.

FIG. 11 is a fragmentary front view of the embodiment, illustrating a state when a releasing member is in abutting engagement with the detent member.

FIG. 12 is a fragmentary rear view of the embodiment, illustrating a state similar to FIG. 11.

FIG. 13 is a fragmentary front view of the embodiment, illustrating a state when the releasing member presses to turn the detent member.

FIG. 14 is a fragmentary rear view of the embodiment, illustrating a state similar to FIG. 13.

FIG. 15 is a fragmentary front view of the embodiment, illustrating a state when the inner rail reaches the middle second end, and a releasing portion of the releasing member is in abutting engagement with the detent member.

FIG. 16 is a perspective view of the embodiment, illustrating the middle rail moved to an extended position.

FIG. 17 is a fragmentary rear view of the embodiment, illustrating a state when the middle rail is in the extended position and an anti-retraction member is in abutting engagement with an outer abutting protrusion.

FIG. 18 is a fragmentary rear view of the embodiment, illustrating a state when the middle rail is in the extended position and the anti-retraction member is turned by a release transmitting member.

FIG. 19 is a fragmentary front view of the embodiment, illustrating a state when the middle rail is in the extended position and a stop and release operating member is in abutting engagement with a middle abutting protrusion.

FIG. 20 is a fragmentary front view of the embodiment, illustrating a state when the middle rail is in the extended position and the stop and release operating member is operably turned to release the engagement from the middle abutting protrusion.

FIG. 21 is a fragmentary rear view of the embodiment, illustrating a state when, during the movement of the middle rail from the extended position to a retreating position, the detent member is turned by the outer abutting protrusion to release the engagement of the detent member from the releasing portion of the releasing member.

### DETAILED DESCRIPTION

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

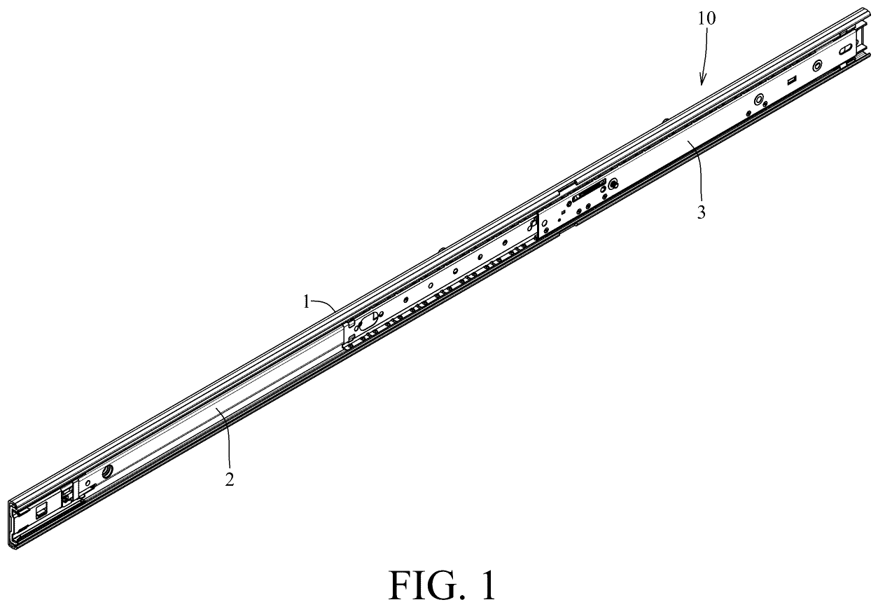

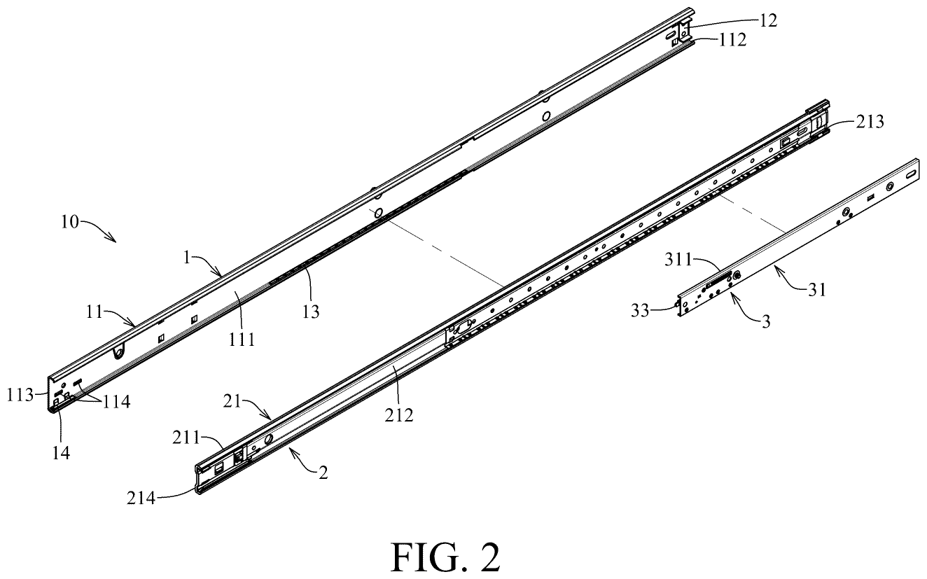

Referring to FIGS. 1 and 2, an embodiment of a slide rail device 10 is adapted for connecting with a server case (not shown) or other electronic devices. The slide rail device 10 includes an outer rail unit 1, a middle rail unit 2 and an inner rail unit 3.

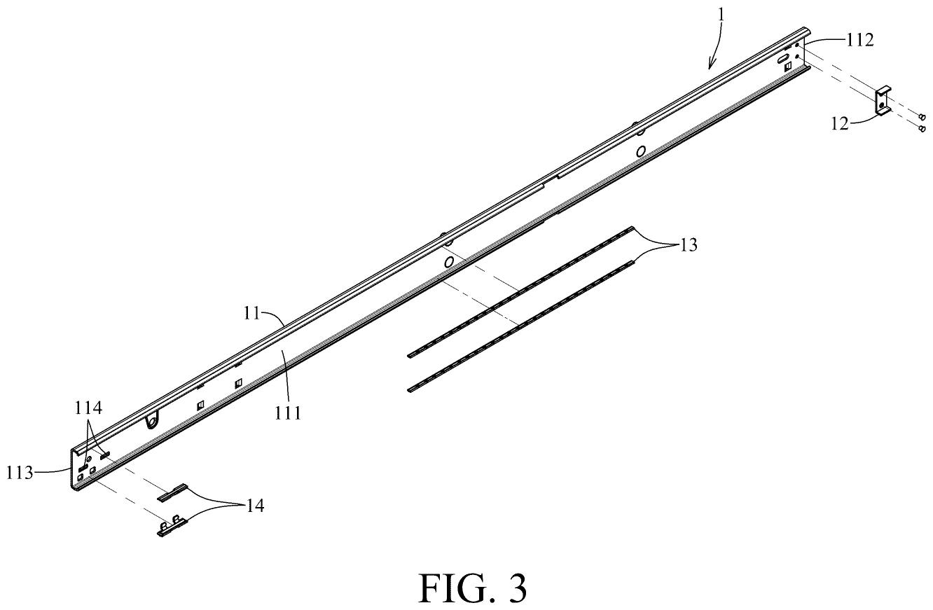

With reference to FIGS. 2 and 3, the outer rail unit 1 includes an outer rail 11, an end stopper 12 disposed on the outer rail 11, two ball strips 13 disposed on the outer rail 11, and two support tabs 14 disposed on the outer rail 11. The outer rail 11 has a moving surface 111, an outer first end 112, an outer second end 113 opposite to the outer first end 112, and two outer abutting protrusions 114 disposed adjacent to the outer second end 113 and spaced apart from each other along a lengthwise direction of the outer rail 11. The end stopper 12 is disposed adjacent to the outer first end 112 to prevent removal of the middle rail unit 2 from the outer first end 112 of the outer rail 11. The ball strips 13 are disposed at upper and lower sides of the outer rail 11 to facilitate sliding of the middle rail unit 2 relative to the outer rail 11. The support tabs 14 are disposed adjacent to the outer second end 113 for supporting the middle rail unit 2 when the middle rail unit 2 is extended forwardly of the outer rail 11.

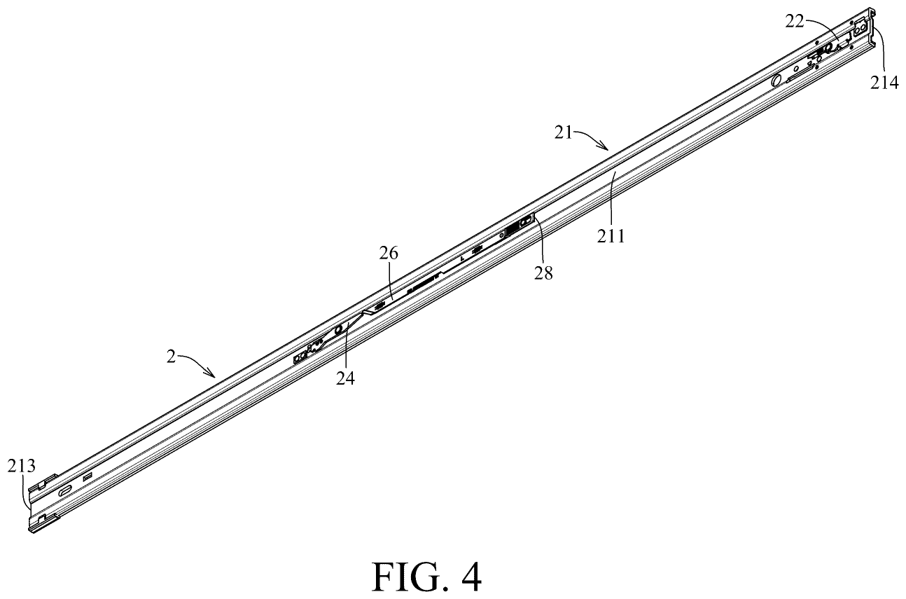

With reference to FIGS. 2, 4 and 5, the middle rail unit 2 includes a middle rail 21 which is disposed on and longitudinally slidable along the outer rail 11, a detent member 22 which is pivotably disposed on the middle rail 21, a first biasing member 23 which is connected with the detent member 22, an anti-retraction member 24 which is pivotably disposed on the middle rail 21, a second biasing member 25 which is connected with the anti-retraction member 24, a release transmitting member 26 which is movably disposed on the middle rail 21, a third biasing member 27 which is connected with the release transmitting member 26, a release operating member 28 which is movably disposed on the middle rail 21 and is abuttingly connected with the release transmitting member 26, and a middle abutting protrusion 29 which is disposed on the middle rail 21. The middle rail 21 has a middle outer surface 211 facing the outer rail 11, a middle inner surface 212 opposite to the middle outer surface 211 and facing the inner rail unit 3, a middle first end 213 adjacent to the outer first end 112 of the outer rail 11, and a middle second end 214 opposite to the middle first end 213. The middle rail 21 is formed with a first engaging slot 215 adjacent to the detent member 22, and a second engaging slot 216 adjacent to the anti-retraction member 24.

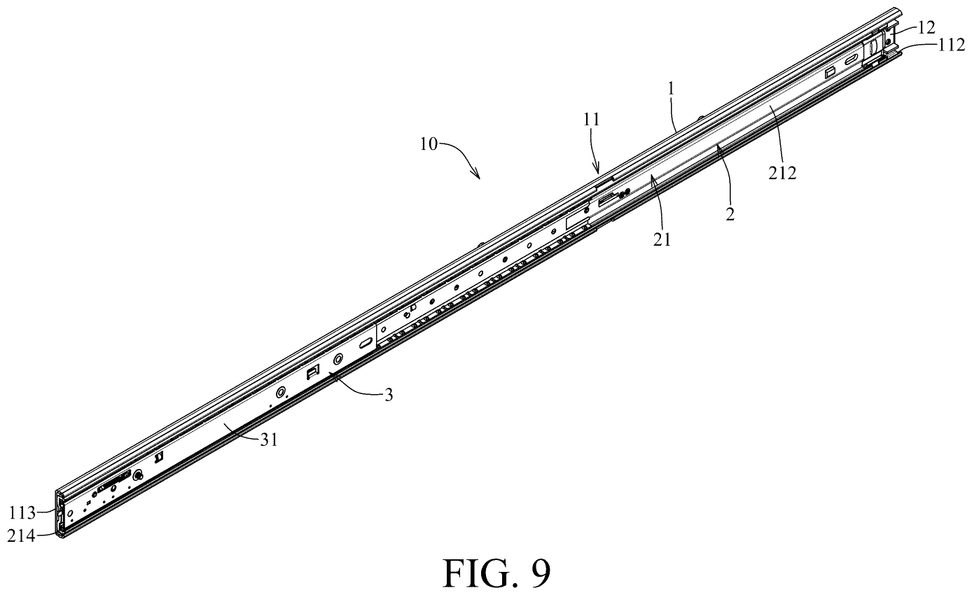

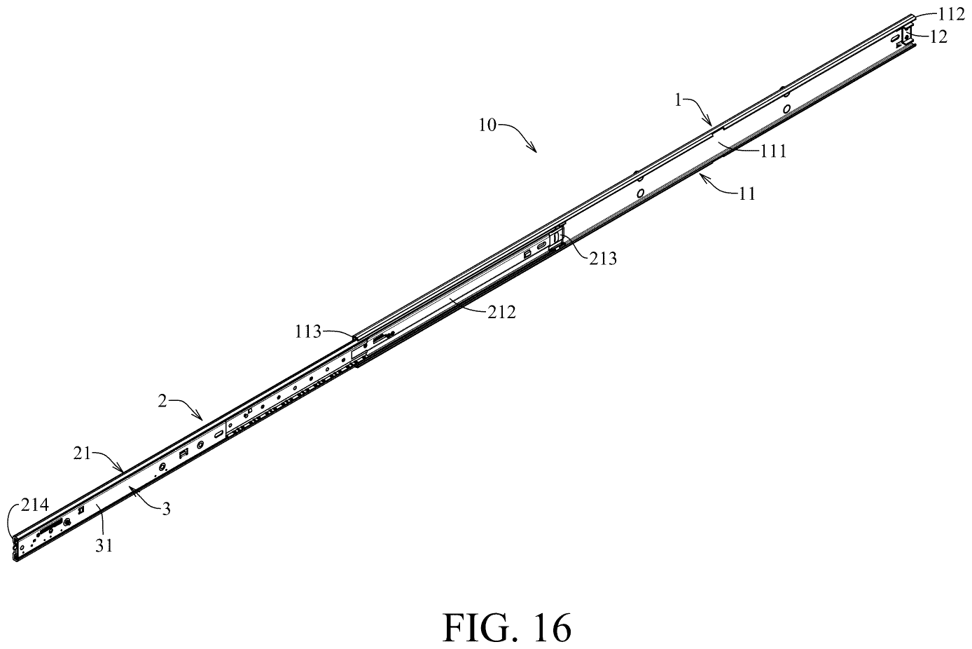

With reference to FIGS. 9 and 16, the middle rail 21 is slidable along the outer rail 11 between a retreating position (see FIG. 9), where the middle rail 21 overlaps the outer rail 11, and an extended position (see FIG. 16), where the middle second end 214 is disposed forwardly of the outer rail 11.

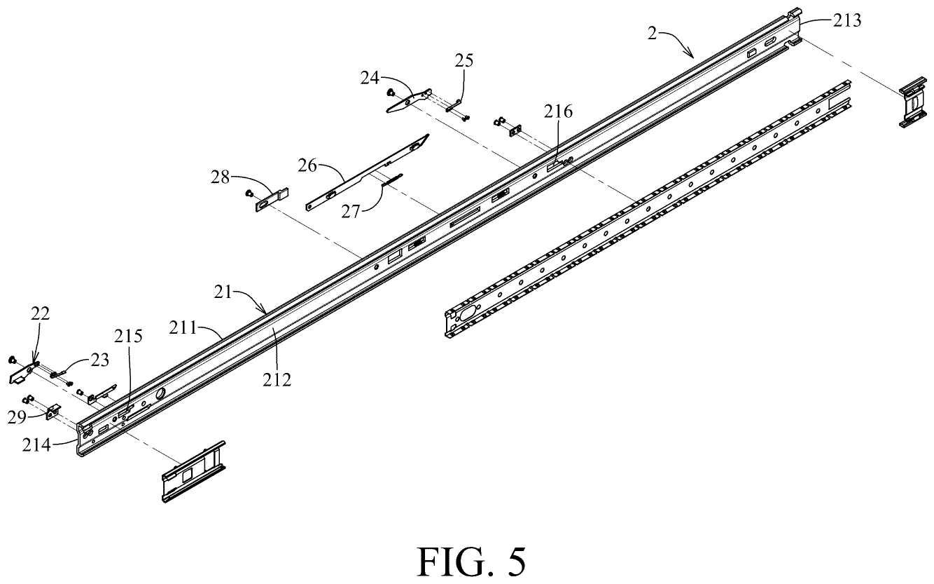

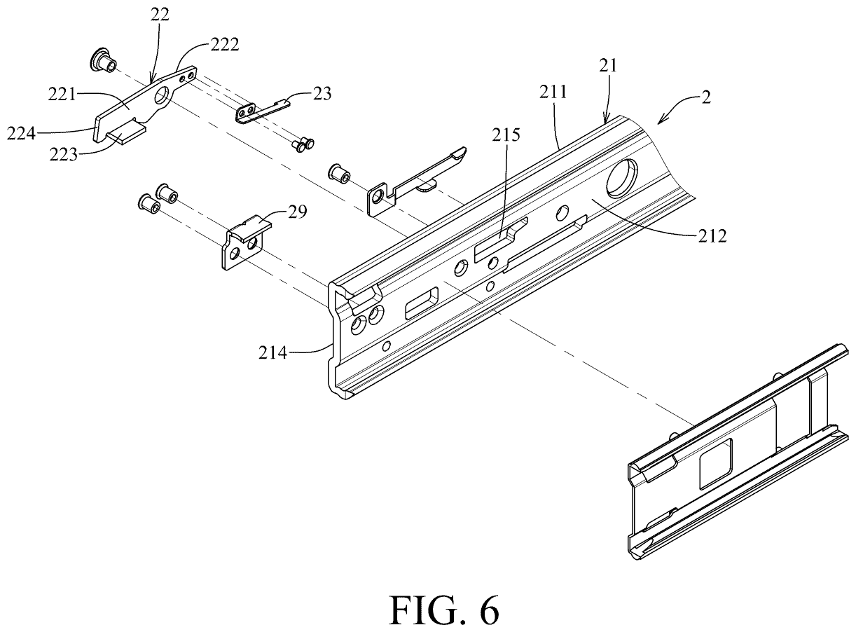

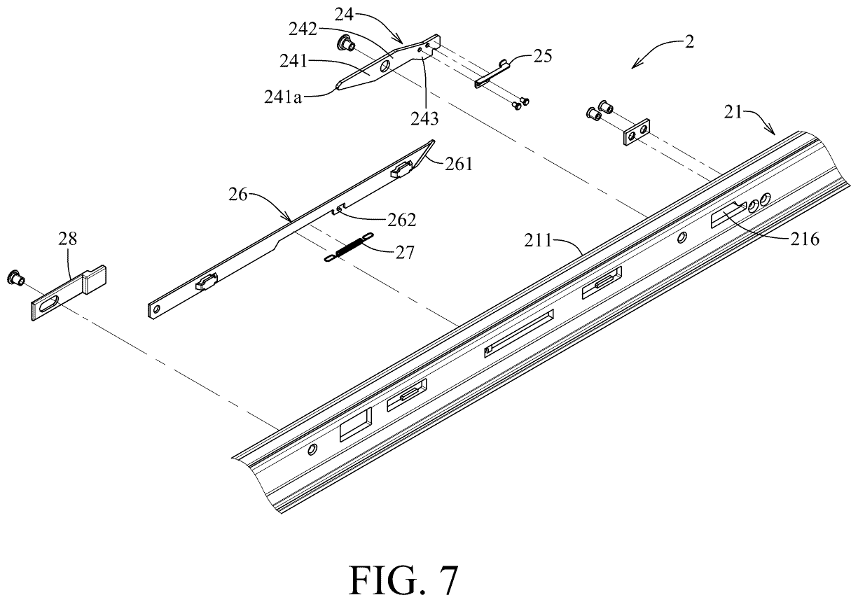

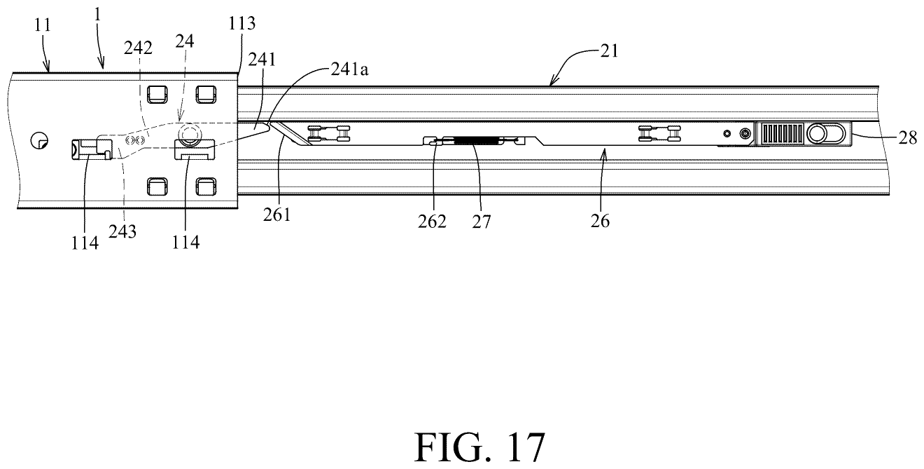

With reference to FIGS. 5 to 7 and FIG. 10, the detent member 22 has a pivot portion 221 which is pivotably connected with the middle outer surface 211 and which has a stopped end 224 facing the middle second end 214, a biasing engaging portion 222 which extends from the pivot portion 221 opposite to the stopped end 224, and a detent portion 223 which extends from and bends relative to the pivot portion 221 through the middle rail 21 and projects outwardly of the middle inner surface 212. The first biasing member 23 has an end connected with the biasing engaging portion 222 of the detent member 22 and is disposed in the first engaging slot 215. The anti-retraction member 24 is brought to be in abutting engagement with one of the outer abutting protrusions 114 (as shown in FIG. 17) when the middle rail 21 is in the extended position to prevent retraction of the middle rail 21 relative to the outer rail 11. The anti-retraction member 24 has a pivot portion 242 which is pivotably connected with the middle outer surface 211, an actuated portion 241 which extends from the pivot portion 242 toward the middle first end 213, and an abutting portion 243 which extends downwardly from the pivot portion 242 and opposite to the actuated portion 241. The abutting portion 243 is brought to be in abutting engagement with the outer abutting protrusion 114 (see FIG. 17) so as to prevent retraction of the middle rail 21 relative to the outer rail 11. The second biasing member 25 has an end connected with the pivot portion 242 of the anti-retraction member 24 near the abutting portion 243, and is disposed in the second engaging slot 216. The release transmitting member 26 is an elongated plate which has an abutting slope 261 at an end thereof, and a hook portion 262. The third biasing member 27 has an end connected with the hook portion 262, and an opposite end connected with the middle rail 21. The actuated portion 241 of the anti-retraction member 24 has an actuated slope 241a facing the abutting slope 261 (see FIG. 17) such that the abutting slope 261 is moved to abut against and press the actuated slope 241a to make the actuated portion 241 turn downwardly, which turns the abutting portion 243 upwardly. The release operating member 28 is operable to move the release transmitting member 26 toward the middle first end 213, which turns the anti-retraction member 24 so as to release engagement of the abutting portion 243 from the outer abutting protrusion 114. The middle abutting protrusion 29 is disposed on the middle rail 21 adjacent to the middle second end 214, and projects from the middle inner surface 212.

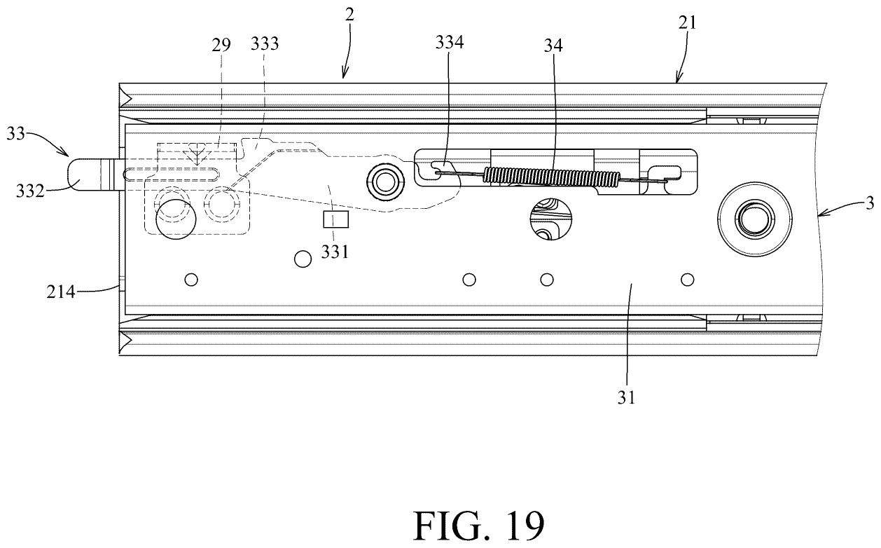

With reference to FIG. 2 and FIGS. 8 to 12, the inner rail unit 3 includes an inner rail 31 which is disposed on and longitudinally slidable along the middle rail 21 for connecting with the server case, a releasing member 32 which is securely disposed on the inner rail 31 to be moved with the inner rail 31, a stop and release operating member 33 which is pivotably disposed on the inner rail 31, and a fourth biasing member 34 which is connected with the stop and release operating member 33. The inner rail 31 has an inner rail surface 311 facing the middle rail 21. The releasing member 32 has an elongated main plate portion 321 which is securely disposed on the inner rail surface 311, and a releasing portion 322 which extends upwardly from the main plate portion 321. Both of the main plate portion 321 and the releasing portion 322 are disposed to abut and press the detent portion 223 of the detent member 22 to make the detent portion 223 turn upward so as to release engagement of the detent portion 223 from the outer abutting protrusion 114. The stop and release operating member 33 has a pivot portion 331 which is pivotably connected with the inner rail 31, an operating portion 332 which extends from the pivot portion 331 toward the middle second end 214 and projects forwardly of the inner rail 31, a stop portion 333 which extends upwardly from the pivot portion 331 and opposite to the operating portion 332 to be in abutting engagement with the middle abutting protrusion 29 (see FIG. 19), and a hook portion 334 which is connected with an end of the pivot portion 331 opposite to the operating portion 332. The fourth biasing member 34 has an end connected with the hook portion 334, and an opposite end connected with the middle rail 21.

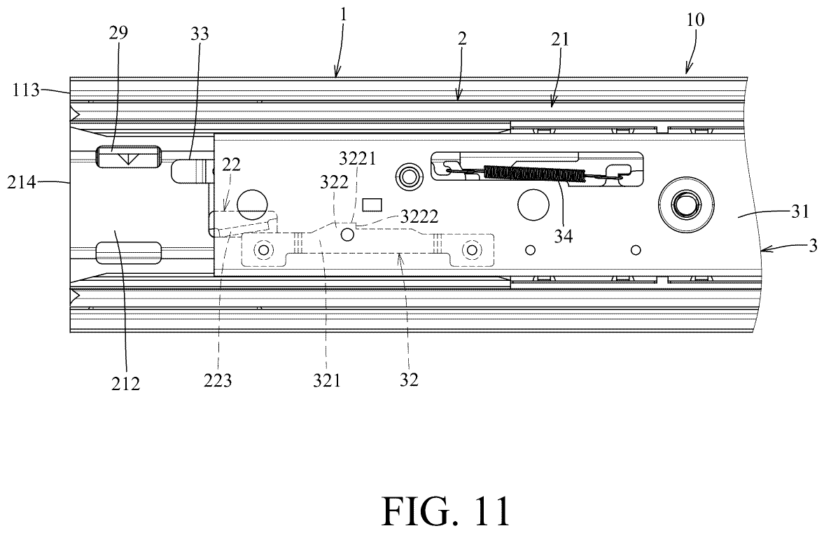

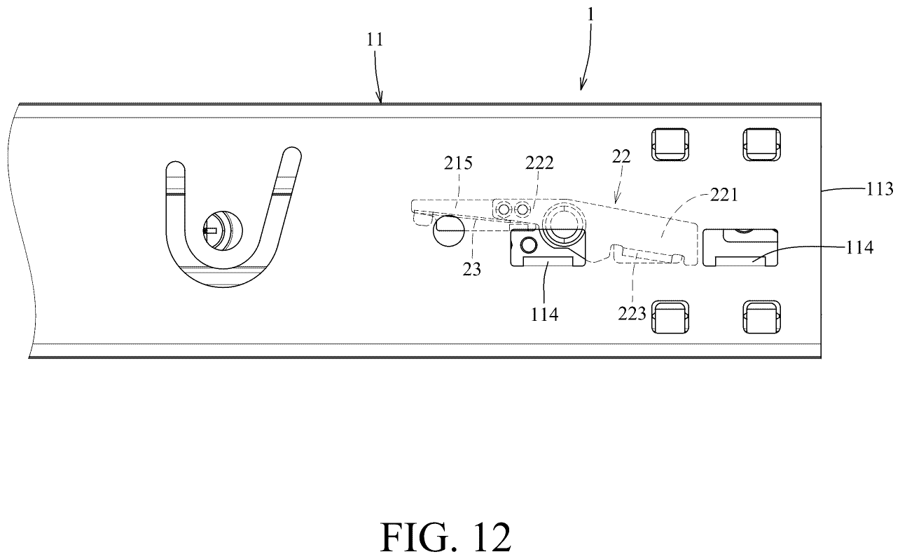

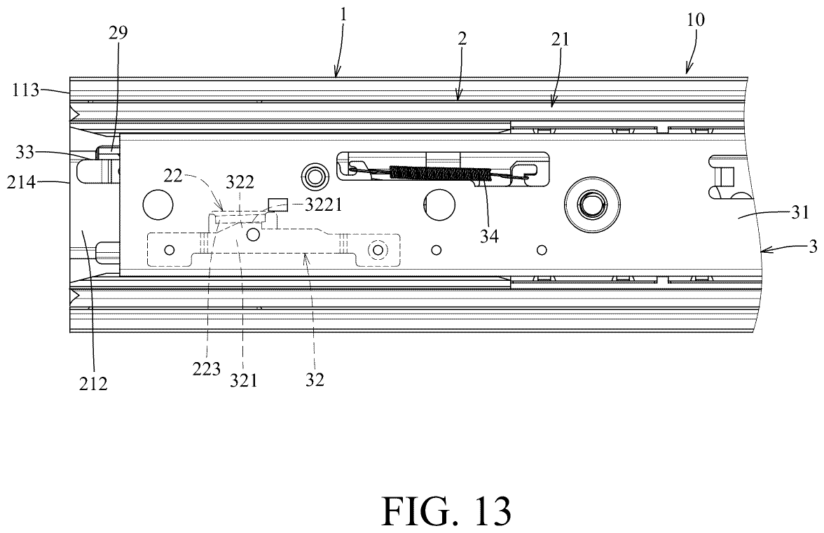

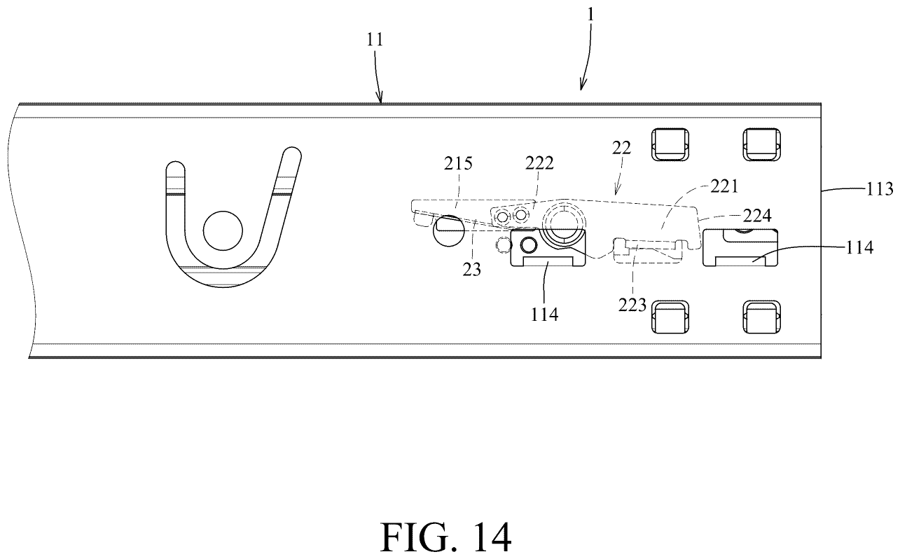

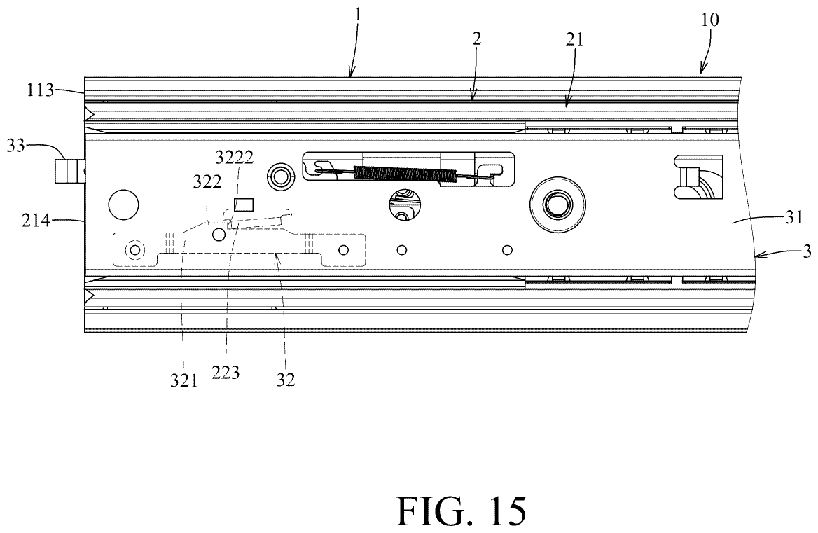

With reference to FIG. 1 and FIGS. 9 to 14, when the middle rail 21 is in the retreating position, the detent member 22 is disposed to be in abutting engagement with the outer abutting protrusion 114 to prevent sliding movement of the middle rail 21 relative to the outer rail 11 in an extended direction (see FIG. 9). During the sliding movement of the inner rail 31 from the middle first end 213 to the middle second end 214, the releasing member 32 is moved to abut and press the detent member 22 to make the detent member 22 turn so as to release engagement of the detent member 22 from the outer abutting protrusion 114. Specifically, the main plate portion 321 of the releasing member 32 firstly abuts against the detent portion 223, as shown in FIGS. 11 and 12. During the movement, the main plate portion 321 presses the detent portion 223 to turn upwardly, and a releasing edge 3221 of the releasing portion 322 is then moved over and presses the detent portion 223 to further turn upwardly so as to disengage the detent member 22 from the outer abutting protrusion 114, as shown in FIGS. 13 and 14, to release engagement of the detent member 22 from the outer abutting protrusion 114 so as to permit sliding movement of the middle rail 21 from the retreating position to the extended position. Subsequently, when the inner rail 31 is moved to the middle second end 214, a retraction actuating edge 3222 of the releasing portion 322 is disposed forwardly of and in abutting engagement with the detent portion 223, as shown in FIG. 15, so as to prevent retreating movement of the inner rail 31 relative to the middle rail 21, and such that the middle rail 21 is synchronously moved with the inner rail 31 in a retreating direction to move the middle rail 21 from the extended position to the retreating position.

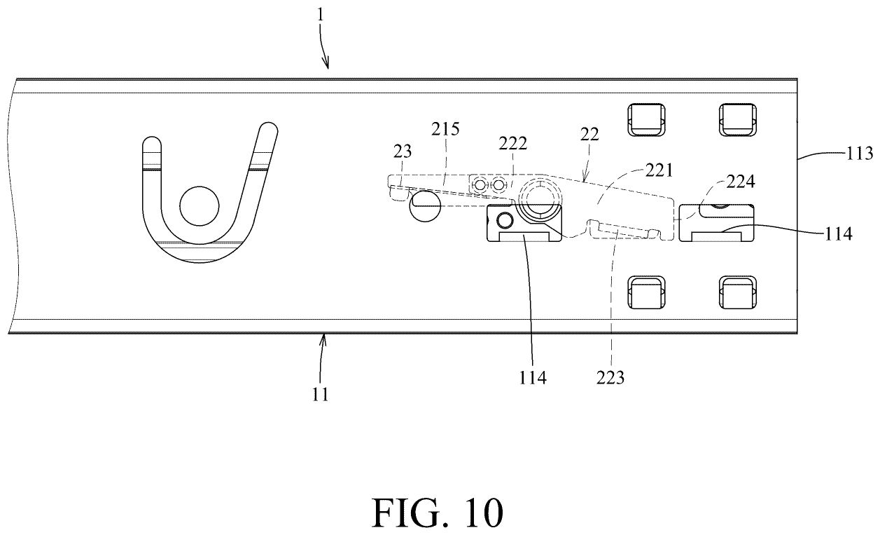

With reference to FIGS. 9 and 10, with the detent member 22 of the middle rail unit 2 in abutting engagement with the outer abutting protrusion 114 when the middle rail 21 is in the retreating position, the sliding movement of the middle rail 21 relative to the outer rail 11 is prevented such that, when the user pulls and moves the server case and the inner rail 31, undesired movement of the middle rail 21 relative to the outer rail 11 and projection of the middle rail 21 from the outer rail 11 may be avoided to prevent injury to the user for improving safety during operation. When the releasing member 32 of the inner rail unit 3 is moved along with the sliding movement of the inner rail 31 to abut and press the detent member 22 and turn the detent member 22 so as to release the engagement of the detent member 22 from the outer abutting protrusion 114, and when the inner rail 31 is moved to the middle second end 214 of the middle rail 21, the middle rail 21 may be moved with the inner rail 31 relative to the outer rail 11 in the extended direction to the extended position, as shown in FIG. 16.

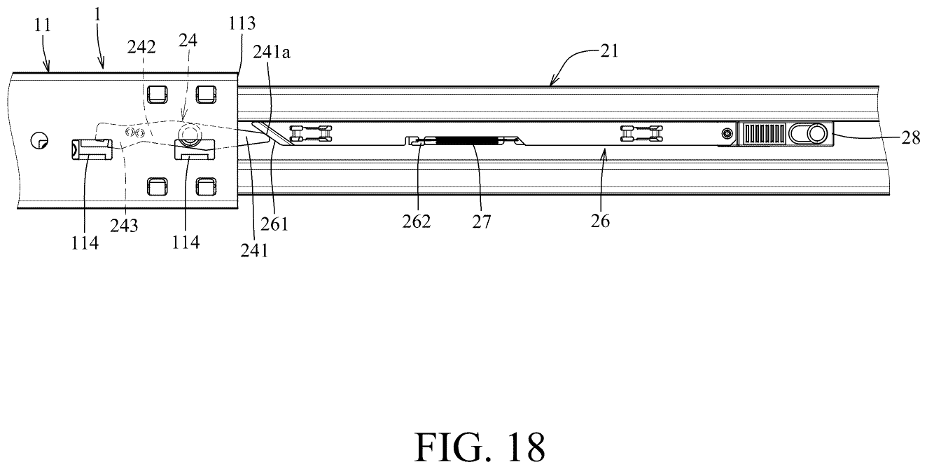

Subsequently, with reference to FIGS. 17 and 18, when the middle rail 21 is moved to the extended position, the anti-retraction member 24 is moved forwardly of and in abutting engagement with the outer abutting protrusion 114 so as to keep the middle rail 21 in the extended position to prevent retreating movement of the middle rail 21 relative to the outer rail 11 in the retreating direction. In this state, the release operating member 28 is operable to move the release transmitting member 26 toward the middle first end 213 (see FIG. 16), which turns the anti-retraction member 24. By virtue of the abutting slope 261 moved to abut against and pressing the actuated slope 241a to make the actuated portion 241 turn downwardly, which turns the abutting portion 243 upwardly, the abutting portion 243 is released from the outer abutting protrusion 114.

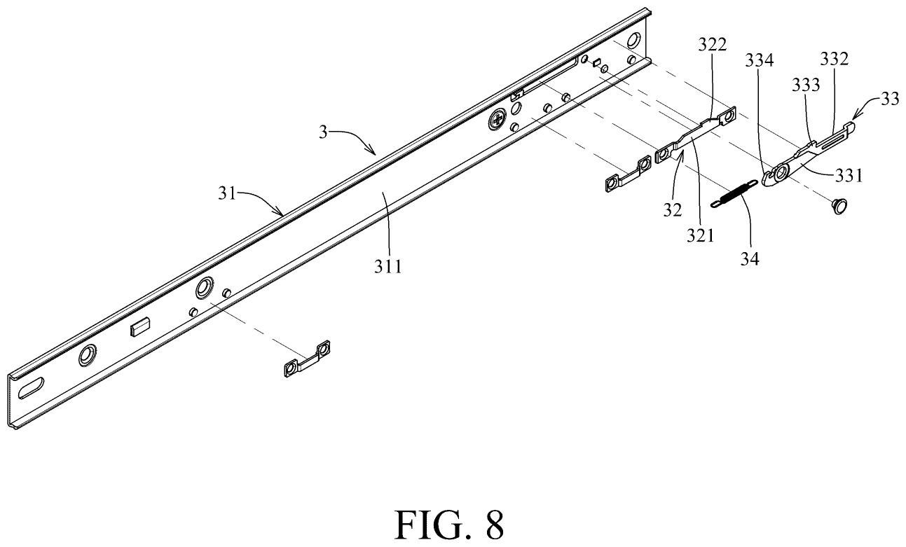

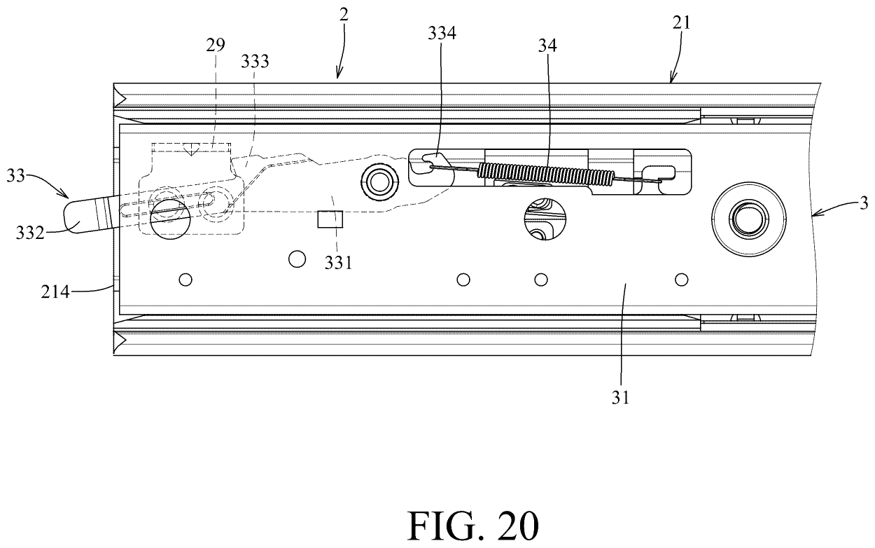

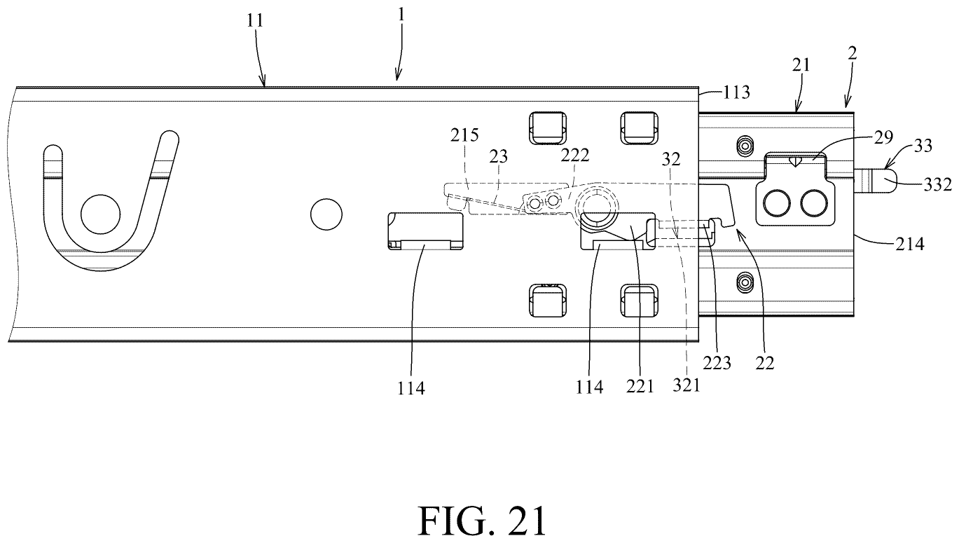

Moreover, with reference to FIGS. 8, 19 and 20, the stop portion 333 of the stop and release operating member 33 is stopped by and engaged with the middle abutting protrusion 29 when the inner rail 31 slides along the middle rail 21 in the extended direction to prevent extension of the inner rail 31 relative to the middle rail 21. Hence, by turning the operating portion 332 of the stop and release operating member 33 downwardly, the stop portion 33 is turned upwardly so as to release the abutting engagement of the stop portion 333 from the middle abutting protrusion 29 such that the server case (not shown) and the inner rail 31 may be further pulled by the user relative to the middle rail 21 and out of the middle rail 21 for maintenance or replacement. With reference to FIG. 21, when it is desired to return the server case and the inner rail 31 to their original positions, i.e., during the movement of the middle rail 21 from the extended position to the retreating position, with the abutting engagement of the detent portion 223 with the releasing portion 322, the retreating movement of the inner rail 31 may make the middle rail 21 move and retreat relative to the outer rail 11. Firstly, the release operating member 28 is operated to release the abutting portion 243 from the outer abutting protrusion 114 (see FIG. 18), and the middle rail 21 is then moved to retreat relative to the outer rail 11 until a lower end of the pivot portion 221 of the detent member 22 abuts against the outer abutting protrusion 114. Subsequently, the lower end of the pivot portion 221 is pressed upwardly by the outer abutting protrusion 114 to turn the detent portion 223 upwardly and release the detent portion 223 from the releasing portion 322. Thus, the server case and the inner rail 31 are permitted to be move relative to the middle rail 21 in the retreating direction so as to not project from the middle second end 214 of the middle rail 21, and the middle rail 21 is returned to the retreating position, as shown in FIG. 9. Finally, the server case and the inner rail 31 are further moved toward the middle first end 213 to return their original position as shown in FIG. 1. Therefore, since the middle rail 21 is retracted relative to the outer rail 11 before the inner rail 31 is retracted, the middle rail 21 does not project from the outer rail 11 during the sliding movement of the inner rail 31 from the middle second end 214 to the middle first end 213, which prevents injury to the user during the retraction operation of the inner rail 31.

As illustrated, with the detent member 22 of the middle rail unit 2 in abutting engagement with the outer abutting protrusion 114 to prevent movement of the middle rail 21 relative to the outer rail 11, undesired movement of the middle rail 21 relative to the outer rail 11 is avoided during pulling of the server case and the inner rail 31 by the user so as to prevent accidental projection of the middle rail 21 from the outer rail 11, which may scratch the user. By preventing the accidental projection of the middle rail 21 from the outer rail 11, safety during operation is improved. Moreover, when the releasing member 32 of the inner rail unit 3 is moved to abut and press the detent member 22 to turn the detent member 22 so as to release the engagement from the outer abutting protrusion 114, and the inner rail 31 is moved to the middle second end 214, the middle rail 21 is permitted to move relative to and to be pulled out of the outer rail 11, which prevents injury to the user by the middle rail 21.

While the disclosure has been described in connection with what is considered the exemplary embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. A slide rail device for connecting with a server case, comprising:
an outer rail unit including an outer rail, said outer rail having an outer first end, an outer second end opposite to said outer first end, and at least one outer abutting protrusion disposed adjacent to said outer second end;
a middle rail unit including a middle rail which is disposed on and longitudinally slidable along said outer rail, and a detent member which is pivotably disposed on said middle rail, said middle rail having a middle first end adjacent to said outer first end, and a middle second end opposite to said middle first end, said detent member being disposed to be in abutting engagement with said outer abutting protrusion to prevent sliding movement of said middle rail relative to said outer rail; and
an inner rail unit including an inner rail which is disposed on and longitudinally slidable along said middle rail for connecting with the server case, and a releasing member which is securely disposed on said inner rail to be moved with said inner rail, wherein, during sliding movement of said inner rail from said middle first end to said middle second end, said releasing member is moved to abut and press said detent member to make said detent member turn so as to release engagement of said detent member from said outer abutting protrusion.

2. The slide rail device of claim 1, wherein said middle rail has a middle outer surface facing said outer rail, and a middle inner surface opposite to said middle outer surface and facing said inner rail, said detent member having a pivot portion which is pivotably connected with said middle outer surface and which has a stopped end in abutting engagement with said outer abutting protrusion, and a detent portion which extends from and bends relative to said pivot portion through said middle rail and projects outwardly of said middle inner surface to be pressed by said releasing member and turn upwardly so as to release the engagement of said detent member from said outer abutting protrusion.

3. The slide rail device of claim 2, wherein said detent member further has a biasing engaging portion extending from said pivot portion opposite to said stopped end, said middle rail having a first engaging slot, said middle rail unit further including a first biasing member which has an end connected with said biasing engaging portion and is disposed in said first engaging slot.

4. The slide rail device of claim 2, wherein said inner rail has an inner rail surface facing said middle rail, said releasing member having a main plate portion which is securely disposed on said inner rail surface, and a releasing portion which extends upwardly from said main plate portion, both of said main plate portion and said releasing portion being disposed to abut and press said detent portion of said detent member to make said detent portion turn upward so as to release engagement of said detent portion from said outer abutting protrusion.

5. The slide rail device of claim 4, wherein said middle rail is slidable along said outer rail between a retreating position, where said middle rail overlaps said outer rail, and an extended position, where said middle second end is disposed forwardly of said outer rail, said releasing portion having a releasing edge and a retraction actuating edge, wherein, during sliding movement of said inner rail along said middle rail from said middle first end to said middle second end and when said middle rail is in the retreating position, said releasing edge is moved over and presses said detent portion to release engagement of said detent member from said outer abutting protrusion so as to permit sliding movement of said middle rail from the retreating position to the extended position, and said retraction actuating edge is then disposed forwardly of and in abutting engagement with said detent portion such that said middle rail is synchronously moved with said inner rail in a retreating direction to move said middle rail from the extended position to the retreating position.

6. The slide rail device of claim 1, wherein said middle rail unit further includes an anti-retraction member which is pivotably disposed on said middle rail, said middle rail being slidable along said outer rail between a retreating position, where said middle rail overlaps said outer rail and said detent member is in abutting engagement with said outer abutting protrusion, and an extended position, where said middle second end is disposed forwardly of said outer rail, wherein, during the sliding movement of said inner rail to said middle second end, said releasing member is moved to release the engagement of said detent member from said outer abutting protrusion to permit sliding movement of said middle rail to the extended position, and to bring said anti-retraction member in abutting engagement with said outer abutting protrusion so as to keep said middle rail in the extended position.

7. The slide rail device of claim 6, wherein said middle rail has a middle outer surface facing said outer rail, and a middle inner surface opposite to said middle outer surface and facing said inner rail, said anti-retraction member having a pivot portion which is pivotably connected with said middle outer surface, an actuated portion which extends from said pivot portion toward said middle first end, and an abutting portion which extends downwardly from said pivot portion and opposite to said actuated portion and which is disposed forwardly of and in abutting engagement with said outer abutting protrusion when said middle rail is moved to the extended position so as to prevent retraction of said middle rail relative to said outer rail.

8. The slide rail device of claim 7, wherein said middle rail unit further includes a release operating member which is movably disposed on said middle outer surface, and a release transmitting member which is connected and moved with said release operating member and which is in abutting engagement with said actuated portion of said anti-retraction member such that said release operating member is operable to move said release transmitting member toward said middle first end, which turns said anti-retraction member so as to release engagement of said abutting portion from said outer abutting protrusion.

9. The slide rail device of claim 8, wherein said release transmitting member has an abutting slope, said actuated portion of said anti-retraction member having an actuated slope facing said abutting slope such that said abutting slope is moved to abut against and press said actuated slope to make said actuated portion turn downwardly, which turns said abutting portion upwardly.

10. The slide rail device of claim 7, wherein said middle rail has a second engaging slot, said middle rail unit further including a second biasing member which has an end connected with said pivot portion of said anti-retraction member and is disposed in said second engaging slot.

11. The slide rail device of claim 2, wherein said middle rail unit further includes a middle abutting protrusion which is disposed on said middle rail adjacent to said middle second end and which projects from said middle inner surface, said inner rail unit further including a stop and release operating member which is pivotably disposed on said inner rail to be stopped by and engaged with said middle abutting protrusion when said inner rail slides along said middle rail in an extended direction, wherein said stop and release operating member is operable to be turned to release the abutting engagement thereof from said middle abutting protrusion.

12. The slide rail device of claim 11, wherein said stop and release operating member has a pivot portion which is pivotably connected with said inner rail, an operating portion which extends from said pivot portion toward said middle second end and projects forwardly of said inner rail, and a stop portion which extends upwardly from said pivot portion and opposite to said operating portion and which is in abutting engagement with said middle abutting protrusion, wherein said operating portion is operably turned downwardly to make said stop portion turn upward so as to release the abutting engagement of said stop portion from said middle abutting protrusion.
